(19) United States
(12) Patent Application Publication
(10) Pub. No.: US 2025/0357334 A1
(43) Pub. Date: Nov. 20, 2025

(54) MANAGING CAPACITORS IN SEMICONDUCTOR DEVICES

(71) Applicant: Yangtze Memory Technologies Co., Ltd., Wuhan (CN)

(72) Inventor: Jinlong FENG, Wuhan (CN)

(21) Appl. No.: 18/790,433

(22) Filed: Jul. 31, 2024

Related U.S. Application Data
(63) Continuation of application No. PCT/CN2024/093343, filed on May 15, 2024.

(51) Int. Cl. H01L 23/528; H10B 12/00

(52) U.S. Cl. CPC H01L 23/528; H10B 12/033; H10B 12/315; H10B 12/485

(57) ABSTRACT

Systems, devices, and methods for managing capacitors in semiconductor devices are provided. In one aspect, a semiconductor device includes capacitors and semiconductor bodies corresponding to the capacitors. The semiconductor bodies each includes a first end coupled to an end of a respective one of the capacitors. The semiconductor device includes a loop-shaped conductive structure including a pair of line segments and a pair of end segments adjoined to ends of the pair of line segments. The pair of line segments is coupled to second ends of the semiconductor bodies. The pair of end segments is coupled to a control circuitry.

### CROSS-REFERENCE TO RELATED APPLICATIONS

This application is a continuation of International Application No. PCT/CN2024/093343, filed on May 15, 2024, the disclosure of which is hereby incorporated by reference in its entirety.

### TECHNICAL FIELD

The present disclosure relates to semiconductor devices and fabrication processes for semiconductor devices.

### BACKGROUND

Semiconductor memory devices may be classified into non-volatile memory devices, such as flash memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

### SUMMARY

The present disclosure describes methods, devices, systems and techniques for managing capacitor structures for control circuitries in three-dimensional (3D) semiconductor devices.

One aspect of the present disclosure features a semiconductor device, including capacitors and semiconductor bodies corresponding to the capacitors. The semiconductor bodies each includes a first end coupled to an end of a respective one of the capacitors. The semiconductor device includes a loop-shaped conductive structure including a pair of line segments and a pair of end segments adjoined to ends of the pair of line segments. The pair of line segments is coupled to second ends of the semiconductor bodies. The pair of end segments is coupled to a control circuitry.

In some implementations, the semiconductor device includes paired conductive vias. First ends of the paired conductive vias are coupled to the pair of end segments of the loop-shaped conductive structure. Second ends of the paired conductive vias are coupled to a conductor. The conductor is coupled to the control circuitry.

In some implementations, the semiconductor device includes memory cells, each including a transistor and a capacitor. The transistor includes a transistor body, a gate structure, a first terminal and a second terminal on opposite ends of the transistor body. The first terminal of the transistor is coupled to the capacitor. The semiconductor device includes bit lines. Each is coupled to corresponding second terminals of the transistors. The semiconductor device includes individual conductive vias. A first one of the individual conductive vias is coupled to a first end of a first bit line of the bit lines. A second one of the individual conductive vias is coupled to a second end of a second bit line adjacent to the first bit line. The first end is opposite to the second end.

In some implementations, the first end of the first bit line extends beyond a first end of the second bit line.

In some implementations, the capacitors, the semiconductor bodies, the loop-shaped conductive structure, and the paired conductive vias are in a semiconductor structure. The semiconductor device further includes a control structure bonded with the semiconductor structure. The control structure including the control circuitry. The capacitors are coupled to the control circuitry through the loop-shaped conductive structure, the paired conductive vias and the conductor.

In some implementations, the semiconductor structure includes one or more first conductive contacts isolated by a first dielectric material. The control structure includes one or more second conductive contacts isolated by a second dielectric material. The one or more first conductive contacts are in contact with the one or more second conductive contacts.

In some implementations, the semiconductor bodies include doped polysilicon with a concentration of dopants greater than 1E15 dopant atoms per cubic centimeter.

In some implementations, the dopants include at least one of Phosphorus (P), Arsenic (As), Boron (B) or Gallium (Ga).

In some implementations, resistance of one of the semiconductor bodies ranges between 100 kiloohms to 500 kiloohms.

In some implementations, the pair of line segments of the loop-shaped conductive structure have a uniform length.

In some implementations, the semiconductor device includes a first region and second regions. The first region including the capacitors, the semiconductor bodies, and the loop-shaped conductive structure. Each of the second regions includes the memory cells and the bit lines. The first region is centered in the second regions.

Another aspect of the present disclosure features a semiconductor device including loop-shaped conductive structures each including a pair of line segments and a pair of end segments adjoined to ends of the pair of line segments. The semiconductor device includes pairs of conductive vias. First ends of each pair of conductive vias is coupled to the pair of end segments of a corresponding one of the loop-shaped conductive structures. The semiconductor device includes conductors, each coupled to second ends of a corresponding pair of the pairs of conductive vias.

In some implementations, each line segment of the pair of line segments extends along a first direction, and the loop-shaped conductive structures are arranged along a second direction perpendicular to the first direction.

In some implementations, the semiconductor device includes capacitors and semiconductor bodies corresponding to the capacitors. Each of the semiconductor bodies each includes a first end coupled to an end of a respective one of the capacitors and a second end coupled to the pair of line segment of a corresponding one of the loop-shaped conductive structures.

In some implementations, the semiconductor bodies include doped polysilicon with a concentration of dopants greater than 1E15 dopant atoms per cubic centimeter.

In some implementations, the dopants include at least one of Phosphorus (P), Arsenic (As), Boron (B) or Gallium (Ga).

In some implementations, resistance of one of the semiconductor bodies ranges between 100 kiloohms to 500 kiloohms.

Another aspect of the present disclosure features a method including forming capacitors and semiconductor bodies corresponding to the capacitors. Each of the semiconductor bodies includes a first end coupled to a respective one of the capacitors. The method includes forming loop-shaped conductive structures each including a pair of line segments and a pair of end segments adjoined to ends of the pair of line segments. The pair of line segments is coupled to second ends of corresponding semiconductor bodies of the semiconductor bodies. The method includes forming pairs of conductive vias. Each pair of conductive vias is coupled to the pair of end segments of a corresponding one of the loop-shaped conductive structures.

In some implementations, forming the loop-shaped conductive structures includes: (i) forming dielectric structures on a semiconductor substrate; (ii) depositing a spacer layer on sidewalls of the dielectric structures; (iii) removing the dielectric structures; and (iv) etching an exposed portion of semiconductor substrate.

In some implementations, the semiconductor bodies include doped polysilicon with a concentration of dopants greater than 1E15 dopant atoms per cubic centimeter.

In some implementations, the dopants include at least one of Phosphorus (P), Arsenic (As), Boron (B) or Gallium (Ga).

In some implementations, resistance of one of the semiconductor bodies ranges between 100 kiloohms to 500 kiloohms.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a cross-sectional view of an example semiconductor device.

FIG. 2A illustrates a plan view of an example semiconductor device.

FIGS. 2B and 2C illustrate schematic views of an example capacitor array of the example semiconductor device of FIG. 2A.

FIGS. 2D and 2E illustrate schematic views of an example memory array of the example semiconductor device of FIG. 2A.

FIG. 3A illustrates a schematic view of equivalent circuits of an example capacitor array.

FIG. 3B illustrates a schematic view of equivalent circuits of an example memory array.

FIGS. 4A-4E illustrate plan views of additional implementations of an example semiconductor device with varied arrangements of first regions and second regions.

FIGS. 5A-5F illustrate top views and cross-section views of an example semiconductor device at various stages of an example process for forming looped-shaped conductive structures and paired conductive vias.

FIG. 6 illustrates a flow diagram of an example process for forming a semiconductor device.

FIG. 7 illustrates a block diagram of a system.

It is to be understood that the various exemplary implementations shown in the figures are merely illustrative representations and are not necessarily drawn to scale.

### DETAILED DESCRIPTION

Complementary Metal-Oxide-Semiconductor (CMOS) control circuitry is commonly used with memory arrays to manage read, write, and other operations within the memory. The control circuitry can include word line drivers, bit line drivers, row decoders, column decoders, and/or control logic, etc. Capacitors are commonly used in the CMOS control circuits. In some cases, due to process complexity and design constraints in CMOS fabrication, it can be difficult to create high capacitance or larger capacitors.

Implementations of the present disclosure provide semiconductor devices and methods to form such semiconductor devices. In some implementations, a semiconductor device includes capacitors and semiconductor bodies corresponding to the capacitors. The semiconductor bodies each includes a first end coupled to an end of a respective one of the capacitors. The semiconductor device includes a loop-shaped conductive structure including a pair of line segments and a pair of end segments adjoined to ends of the pair of line segments. The pair of line segments is coupled to second ends of the semiconductor bodies. The pair of end segments is coupled to a control circuitry.

Implementations of the present disclosure can provide one or more of the following technical advantages and/or benefits. By using a portion of the capacitors in the memory array to provide capacitors to the CMOS circuits, the existing resource can be effectively utilized, which helps mitigate the need for additional steps for CMOS capacitor fabrication. In addition, transforming two bit lines into a loop-shaped structure for a capacitor array can allow paired conductive vias to connect at both ends of a single line segment of the loop-shaped structure. This configuration can also reduce the total resistance of the circuit and mitigate potential risks of short circuit. Lower resistance in CMOS control circuits can allow faster operations, reduce power consumption, improve signal integrity, and/or improve thermal performance.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

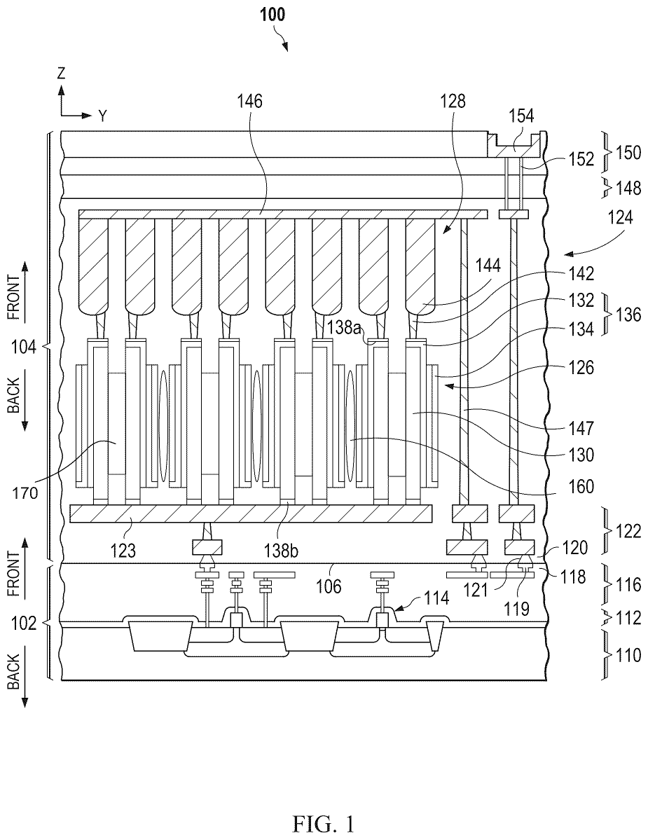

FIG. 1 illustrates a side view of a cross-section of an example 3D semiconductor device 100. The 3D semiconductor device 100 can be a 3D dynamic random-access memory (DRAM). It is understood that FIG. 1 is for illustrative purposes only and may not necessarily reflect the actual device structure (e.g., interconnections) in practice. In some implementations, the 3D semiconductor device 100 is a bonded chip including a first semiconductor structure 102 and a second semiconductor structure 104 stacked over the first semiconductor structure 102. The first and second semiconductor structures 102 and 104 can be jointed at bonding interface 106 therebetween.

As shown in FIG. 1, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on and/or in the substrate 110. In some implementations, the peripheral circuits 112 include a plurality of transistors 114 (e.g., planar transistors and/or 3D transistors). Trench isolations (e.g., shallow trench isolations (STIs)) and doped regions (e.g., wells, sources, and drains of transistors 114) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die 102.

In some implementations, the first semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and VIA contacts. The interconnect layer 116 can further include one or more interlay dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 1, the first semiconductor structure 102 has a front side and a back side, and the first semiconductor structure 102 can further include a bonding layer 118 at the back side at the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. Similarly, as shown in FIG. 1, the second semiconductor structure 104 can also include a bonding layer 120 at the bonding interface 106 and above the bonding layer 118 of the first semiconductor structure 102. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 1. The dielectric layer can include the bonding interface 106 having the bonding contacts 121.

The second semiconductor structure 104 can be bonded on top of the first semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 of the first semiconductor structure 102 and the bottom surface of the bonding layer 120 of the second semiconductor structure 104.

In some implementations, the second semiconductor structure 104 further includes an interconnect layer 122 including bit lines 123 above the bonding layer 120 to transfer electrical signals. The interconnect layer 122 can include a plurality of interconnects, such as mid end of line (MEOL) interconnects and back end of line (BEOL) interconnects. In some implementations, the interconnects in interconnect layer 122 also include local interconnects, such as the bit lines 123 and word line contacts (not shown). The interconnect layer 122 can further include one or more ILD layers in which the interconnect lines and via contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the bit lines 123 and bit line contacts in the interconnect layer 122 through the bonding contacts 121 and 119 in the bonding layers 120 and 118 and the interconnect layer 116. In some implementations, the bit line 123 is a metal bit line, as opposed to semiconductor bit lines (e.g., doped silicon bit lines). For example, the bit line 123 may include W, Co, Cu, Al, or any other suitable metals having higher conductivities than doped silicon. In some implementations, the bit line contact is an ohmic contact as opposed to a Schottky contact.

In some implementations, the bit line 123 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

In some implementations, the second semiconductor structure 104 includes a DRAM device in which memory cells are provided in the form of an array of DRAM cells 124 above the interconnect layer 122 and the bonding layer 120. That is, the interconnect layer 122 including the bit lines 123 can be disposed between bonding layer 120 and array of DRAM cells 124. A bit line 123 in the interconnect layer 122 can be coupled to a string of DRAM cells 124. In some implementations, the second semiconductor structure 104 is formed on a semiconductor die and can be referred to as array die 104.

In some implementations, a semiconductor device can include multiple array dies (e.g., the array die 104) and a CMOS die (e.g., the CMOS die 102). The multiple array dies and the CMOS die can be stacked and bonded together. The CMOS die can be respectively coupled to each of the multiple array dies, and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each DRAM cell 124 can include a vertical transistor 126 and a capacitor 128 coupled to the vertical transistor 126. DRAM cell 124 can be a 1T1C cell consisting of one transistor and one capacitor. It is understood that DRAM cell 124 may be of any suitable configurations, such as 2T1C cell, 3T1C cell, etc. The vertical transistor 126 can be a MOSFET used to switch a respective DRAM cell 124. In some implementations, the vertical transistor 126 includes a transistor body 130 (the active region in which a channel can form) extending vertically (in the Z-direction), and a gate structure 136 in contact with one side of transistor body 130. In a single-gate vertical transistor, the transistor body 130 can have a cuboid shape or a cylinder shape, and the gate structure 136 can abut a single side of transistor body 130 in a plane view, e.g., as shown in FIG. 1. In some implementations, the vertical transistor 126 has a structure including two or more gates, e.g., a two-gates structure, a three-gates structure, or a gate all around (GAA) structure. In some implementations, the gate structure 136 includes a gate electrode 134 and a gate dielectric 132 laterally between the gate electrode 134 and the transistor body 130 in a bit line direction (e.g., in the Y direction). In some implementations, the gate dielectric 132 abuts one side of the transistor body 130, and the gate electrode 134 abuts the gate dielectric 132.

As shown in FIG. 1, in some implementations, the transistor body 130 has two ends (the upper end and lower end in FIG. 1) in the vertical direction (the Z-direction), and at least one end (e.g., the lower end) extends beyond gate dielectric 132 in the vertical direction (the Z-direction) into the ILD layers. In some implementations, one end (e.g., the upper end) of the transistor body 130 is flush with the respective end (e.g., the upper end) of the gate dielectric 132. In some implementations, both ends (the upper end and lower end) of the transistor body 130 extend beyond the gate electrode 134, respectively, in the vertical direction (the Z-direction) into ILD layers. That is, the transistor body 130 can have a larger vertical dimension (e.g., the depth) than that of the gate electrode 134 (e.g., in the Z-direction), and neither the upper end nor the lower end of transistor body 130 is flush with the respective end of the gate electrode 134. Thus, short circuits between the bit lines 123 and the word lines/gate electrodes 134 or between the word lines/gate electrodes 134 and the capacitors 128 can be avoided. The vertical transistor 126 can further include a source and a drain (both referred to as 138 as their locations may be interchangeable) disposed at the two ends (the upper end and lower end) of the transistor body 130, respectively, in the vertical direction (the Z-direction). Source can also be referred to as the first terminal 138a in this disclosure. Drain can also be referred to as the second terminal 138b in this disclosure. In some implementations, one of the source and drain 138 (e.g., at the upper end in FIG. 1) is coupled to the capacitor 128, and the other one of source and drain 138 (e.g., at the lower end in FIG. 1) is coupled to the bit line 123. That is, the vertical transistor 126 can have a first terminal in the positive Z-direction and a second terminal opposite the first terminal in the negative Z-direction, as shown in FIG. 1.

In some implementations, the transistor body 130 includes semiconductor materials, such as single crystalline silicon, polysilicon, amorphous silicon, Ge, any other semiconductor materials, or any combinations thereof. In one example, transistor body 130 may include single crystalline silicon. Source and drain 138 can be doped with N+ type dopants (e.g., Phosphorus (P) or Arsenic (As)) or P-type dopants (e.g., Boron (B) or Gallium (Ga)) at a desired doping level. In some implementations, a silicide layer, such as a metal silicide layer, is formed between source/drain 138 of the vertical transistor 126 and the bit line 123 as the bit line contact or between source/drain 138 of the vertical transistor 126 and the first electrode of the capacitor 128 as capacitor contact 142 to reduce the contact resistance. In some implementations, gate dielectric 132 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, gate electrode 134 includes a conductive material including, but not limited to W, Co, Cu, Al, TiN, TaN, polysilicon, silicide, or any combination thereof. In some implementations, the gate electrode 134 includes multiple conductive layers, such as a W layer over a TiN layer. In one example, the gate structure 136 may be a “gate oxide/gate poly” gate in which the gate dielectric 132 includes silicon oxide and gate electrode 134 includes doped polysilicon. In another example, gate structure 136 may be an HKMG in which gate dielectric 132 includes a high-k dielectric and gate electrode 134 includes a metal.

As described above, since the gate electrode 134 may be part of a word line or extend in the word line direction (e.g., the X direction) as a word line, the second semiconductor structure 104 of the 3D semiconductor device 100 can also include a plurality of word lines each extending in the word line direction. Each word line 134 can be coupled to a row of DRAM cells 124. That is, the bit line 123 and the word line 134 can extend in two perpendicular lateral directions, and the transistor body 130 of the vertical transistor 126 can extend in the vertical direction perpendicular to the two lateral directions in which the bit line 123 and the word line 134 extend. Word lines 134 are in contact with word line contacts (not shown). In some implementations, the word lines 134 include conductive materials including, but not limited to W, Co, Cu, Al, TiN, TaN, polysilicon, silicides, or any combination thereof. In some implementations, the word line 134 includes multiple conductive layers, such as a W layer over a TiN layer, as shown in FIG. 1.

In some implementations, as shown in FIG. 1, the vertical transistor 126 extends vertically through and contacts the word lines 134, and the source or drain 138 of vertical transistor 126 at the lower end thereof is in contact with the bit line 123 (or bit line contact if any). Accordingly, the word lines 134 and the bit lines 123 can be disposed in different planes in the vertical direction due to the vertical arrangement of vertical transistor 126, which simplifies the routing of the word lines 134 and the bit lines 123. In some implementations, the bit lines 123 are disposed vertically between the bonding layer 120 and the word lines 134, and the word lines 134 are disposed vertically between the bit lines 123 and the capacitors 128. The word lines 134 can be coupled to the peripheral circuits 112 in the first semiconductor structure 102 through word line contacts (not shown) in the interconnect layer 122, the bonding contacts 121 and 119 in the bonding layers 120 and 118, and the interconnects in the interconnect layer 116. Similarly, the bit lines 123 in the interconnect layer 122 can be coupled to the peripheral circuits 112 in the first semiconductor structure 102 through the bonding contacts 121 and 119 in the bonding layers 120 and 118 and the interconnects in the interconnect layer 116.

In some implementations, the vertical transistors 126 can be arranged in a mirror-symmetric manner to increase the density of DRAM cells 124 in the bit line direction (the Y direction). As shown in FIG. 1, two adjacent vertical transistors 126 in the bit line direction are mirror-symmetric to one another with respect to a trench isolation 160. That is, the second semiconductor structure 104 can include a plurality of trench isolations 160 each extending in the word line direction (the X direction) in parallel with word lines 134 and disposed between vertical gates 134 of two adjacent rows of the vertical transistors 126. In some implementations, the rows of vertical transistors 126 separated by the trench isolation 160 are mirror-symmetric to one another with respect to the trench isolation 160. The trench isolation 160 can be formed with dielectric materials including, but not limited to, silicon oxide, silicon nitride, silicon oxynitride, low-k dielectrics, or any combination thereof. It is understood that the trench isolation 160 may include an air gap each disposed laterally between adjacent vertical gates 134. Air gaps may be formed due to the relatively small pitches of vertical transistors 126 in the bit line direction (e.g., the Y direction). On the other hand, the relatively small dielectric constant of air in air gaps (e.g., about ¼ of the dielectric constant of silicon oxide) can improve the insulation effect between vertical transistors 126 (and rows of DRAM cells 124) compared with some dielectrics (e.g., silicon oxide). Similarly, in some implementations, air gaps are formed laterally between word lines/gate electrodes 134 in the bit line direction as well, depending on the pitches of word lines/gate electrodes 134 in the bit line direction.

In some implementations, instead of the trench isolation 160 having the air gap being disposed between adjacent vertical gates 134 of two adjacent rows of the vertical transistors 126, a shielding conductive structure 170 (e.g., including metal such as W) is disposed between adjacent transistor bodies 130 of two adjacent rows of vertical transistors 126. The shielding conductive structure 170 can be in contact with at least one of the adjacent transistor bodies 130 and can be coupled to a low voltage (e.g., a fixed negative voltage), which can reduce charge build-up in the memory cells 124, thereby mitigating the floating body effect in the memory cells 124. Moreover, by applying a fixed low voltage on the shielding conductive structure 170 between the memory cells 124, a threshold voltage of the memory cells 124 can be conveniently adjusted, which can reduce the overall manufacturing complexity and cost, and improve reliability of the memory cells 124. Further, the conductive structure 170 can be coupled out from a same side as word lines or a different side from the word lines. For example, the shielding conductive structure 170 can be coupled out from the back side of the second semiconductor structure 104. The shielding conductive structure 170 can be also referred as shielding conductive material. The trench isolation having such shielding conductive structure 170 may be also referred to as trench isolation (TISO) in this disclosure.

As shown in FIG. 1, in some implementations, a capacitor 128 includes a first electrode 144 above and coupled to the source or drain 138 of vertical transistor 126, e.g., the upper end of the transistor body 130, via a capacitor contact 142. In some implementations, the capacitor contact 142 is an ohmic contact, such as a metal silicide contact, as opposed to a Schottky contact. For example, the capacitor contact 142 may include metal silicides, such as WSi, CoSi, CuSi, AlSi, or any other suitable metal silicides having higher conductivities than doped silicon. The capacitor 128 can also include a capacitor dielectric above and in contact with the first electrode 144, and a second electrode above and in contact with the capacitor dielectric. That is, the capacitor 128 can be a vertical capacitor in which the electrodes and capacitor dielectric are stacked vertically (in the Z-direction), and the capacitor dielectric can be sandwiched between the electrodes. In some implementations, each first electrode is coupled to source or drain 138 of a respective vertical transistor 126 in the same DRAM cell, while all second electrodes are coupled to a common plate 146 coupled to the ground, e.g., a common ground. The capacitor 128 can have a first end in the negative Z-direction and a second end opposite the first end in the positive Z-direction, as shown in FIG. 1. In some implementations, the first end of the capacitor 128 is coupled to the first terminal of the vertical transistor 126 via an ohmic contact (e.g., the capacitor contact 142 made of a metal silicide material). As shown in FIG. 1, the second semiconductor structure 104 can further include a capacitor contact 147 (e.g., a conductor) in contact with a common plate 146 for coupling the capacitors 128 to the peripheral circuits 112 or to the ground directly. In some implementations, the capacitor contact 147 (e.g., a conductor) extends in the Z-direction from the dielectric layer of the bonding layer 120 to couple to the second end of the capacitor 128 via the common plate 146, as shown in FIG. 1. In some implementation, the ILD layer in which the capacitors 128 are formed has the same dielectric material as the two ILD layers into which the transistor body 130 extends, such as silicon oxide.

It is understood that the structure and configuration of a capacitor 128 are not limited to the example in FIG. 1 and may include any suitable structure and configuration, such as a planar capacitor, a stack capacitor, a multi-fins capacitor, a cylinder capacitor, a trench capacitor, or a substrate-plate capacitor. In some implementations, the capacitor dielectric includes dielectric materials, such as silicon oxide, silicon nitride, or high-k dielectrics including, but not limited to, Al₂O₃, HfO₂, Ta₂O₅, ZrO₂, TiO₂, or any combination thereof. It is understood that in some examples, a capacitor 128 may be a ferroelectric capacitor used in a FRAM cell, and the capacitor dielectric may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 1, vertical transistor 126 extends vertically through and contacts the word lines 134, source or drain 138 of vertical transistor 126 at the lower end thereof is in contact with the bit line 123, and source or drain 138 of vertical transistor 126 at the upper end thereof is coupled to the capacitor 128. That is, the bit line 123 and the capacitor 128 can be disposed in different planes in the vertical direction and coupled to opposite ends of vertical transistor 126 of DRAM cell 124 in the vertical direction due to the vertical arrangement of vertical transistor 126. In some implementations, the bit line 123 and the capacitor 128 are disposed on opposite sides of the vertical transistor 126 in the vertical direction, which simplifies the routing of the bit lines 123 and reduces the coupling capacitance between the bit lines 123 and the capacitors 128 compared with DRAM cells in which the bit lines and capacitors are disposed on the same side of the planar transistors.

As shown in FIG. 1, in some implementations, the vertical transistors 126 are disposed vertically between the capacitors 128 and the bonding interface 106. That is, the vertical transistors 126 can be arranged closer to the peripheral circuits 112 of the first semiconductor structure 102 and the bonding interface 106 than the capacitors 128. Since the bit lines 123 and the capacitors 128 are coupled to opposite ends of the vertical transistors 126, the bit lines 123 (as part of the interconnect layer 122) are disposed vertically between the vertical transistors 126 and the bonding interface 106 As a result, the interconnect layer 122 including bit lines 123 can be arranged close to the bonding interface 106 to reduce the interconnect routing distance and complexity.

In some implementations, the second semiconductor structure 104 further includes a substrate 148 disposed above the DRAM cells 124. The substrate 148 can be part of a carrier wafer. It is understood that in some examples, the substrate 148 may not be included in the second semiconductor structure 104.

As shown in FIG. 1, the second semiconductor structure 104 can further include a pad-out interconnect layer 150 above the substrate 148 and the DRAM cells 124. The pad-out interconnect layer 150 can include interconnects, e.g., contact pads 154, in one or more ILD layers. The pad-out interconnect layer 150 and the interconnect layer 122 can be formed on opposite sides of the DRAM cells 124. The capacitors 128 can be disposed vertically between the vertical transistors 126 and the pad-out interconnect layer 150. In some implementations, the interconnects in pad-out interconnect layer 150 can transfer electrical signals between the 3D semiconductor device 100 and outside circuits, e.g., for pad-out purposes.

In some implementations, the second semiconductor structure 104 further includes one or more contacts 152 extending through the substrate 148 and part of the pad-out interconnect layer 150 to couple the pad-out interconnect layer 150 to the DRAM cells 124 and the interconnect layer 122. As a result, the peripheral circuits 112 can be coupled to the DRAM cells 124 through the interconnect layers 116 and 122 as well as the bonding layers 120 and 118, and the peripheral circuits 112 and the DRAM cells 124 can be coupled to outside circuits through contacts 152 and pad-out interconnect layer 150. Contact pads 154 and contacts 152 can include conductive materials including, but not limited to, W, Co, Cu, Al, silicides, or any combination thereof. In one example, the contact pad 154 may include Al, and the contact 152 may include W. In some implementations, the contact 152 includes a via surrounded by a dielectric spacer (e.g., having silicon oxide) to electrically separate the via from substrate 148. Depending on the thickness of substrate 148, contact 152 can be an ILV having a depth in the submicron level (e.g., between 10 nm and 1 μm), or a TSV having a depth in the micron- or tens micron-level (e.g., between 1 μm and 100 μm).

Although not shown, it is understood that the pad-out of 3D memory devices is not limited to from the second semiconductor structure 104 having DRAM cells 124 as shown in FIG. 1 and may be from the first semiconductor structure 102 having peripheral circuit 112. Although not shown, it is also understood that the air gaps between word lines 134 and/or between transistor bodies 130 may be partially or fully filled with dielectrics. Although not shown, it is further understood that more than one array of DRAM cells 124 may be stacked over one another to vertically scale up the number of DRAM cells 124.

In some implementations, instead of having the substrate 148 above the DRAM cells 124 as shown in FIG. 1, the second semiconductor structure 104 includes a substrate disposed below the DRAM cells 124. The substrate can be part of a carrier wafer. The DRAM cells 124 can be formed in a front side of the substrate, and the bit lines 123 can be formed in a back side of the substrate. The bit lines 123 can be conductively coupled to the DRAM cells 124 (e.g., the terminals 138 of the vertical transistors 126) through the substrate.

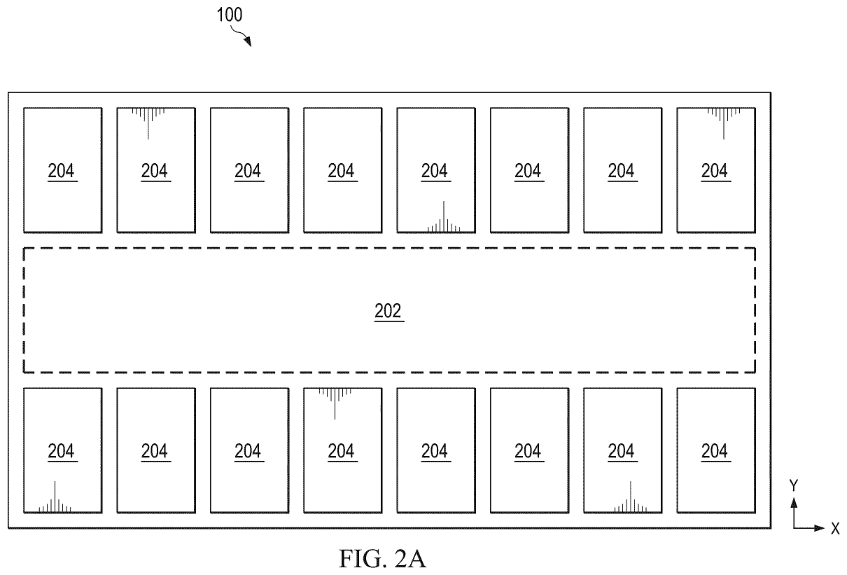

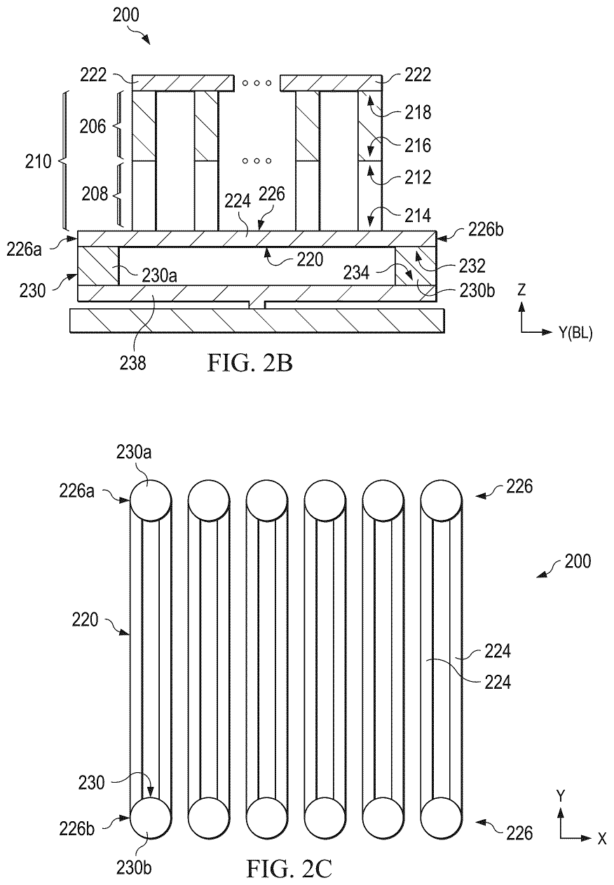

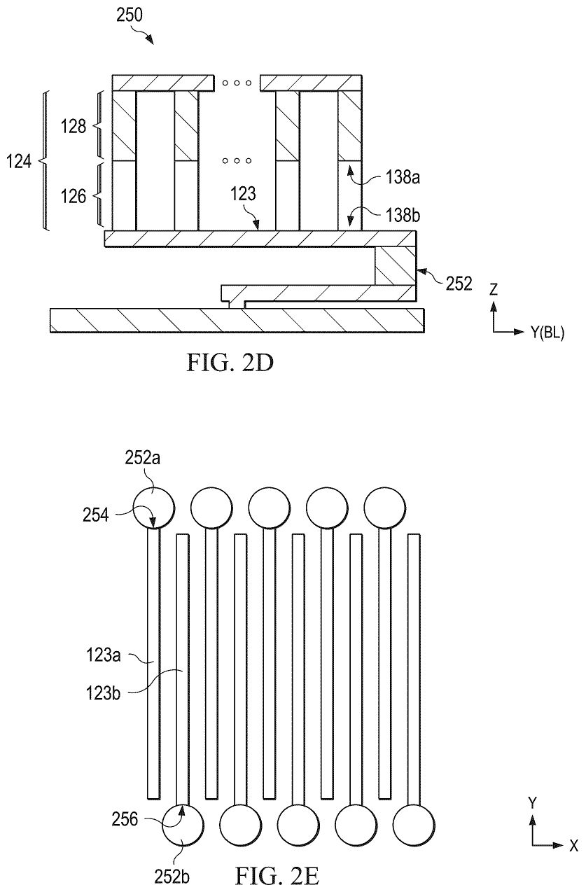

FIGS. 2A-2E illustrate schematic views of the semiconductor device 100. FIG. 2A illustrates a plan view of the semiconductor device 100. FIGS. 2B-2C illustrate schematic views of example capacitor array 200 of the semiconductor device 100. FIGS. 2D-2E illustrate schematic views of example memory arrays 250 of the semiconductor device 100.

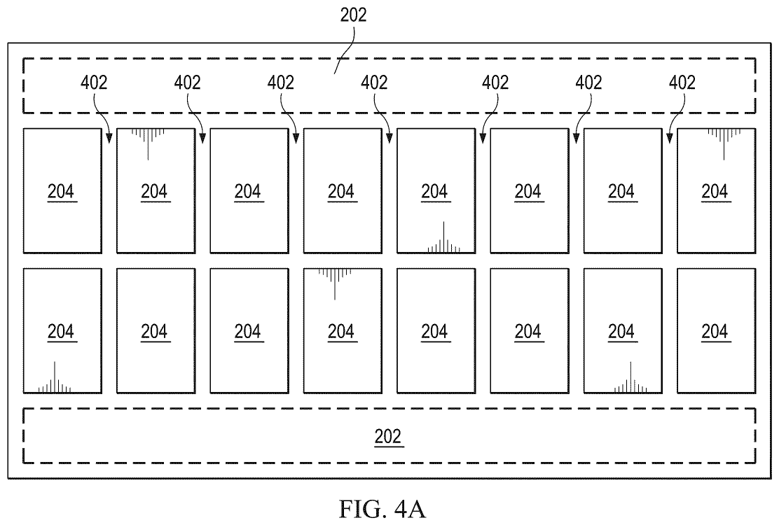

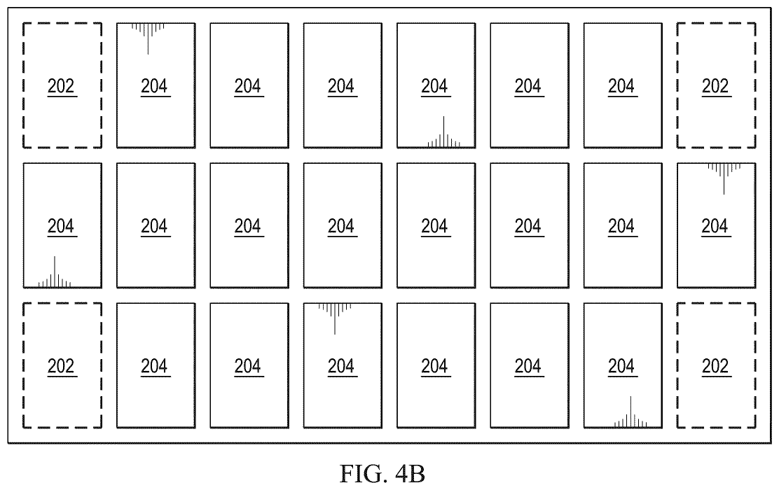

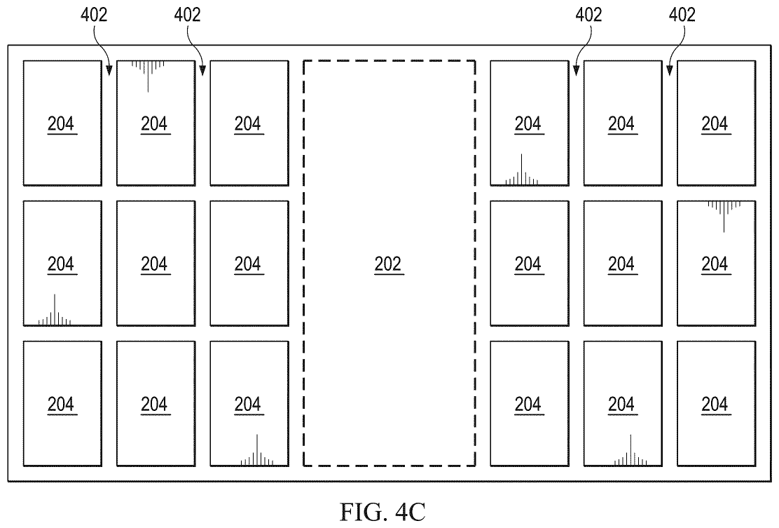

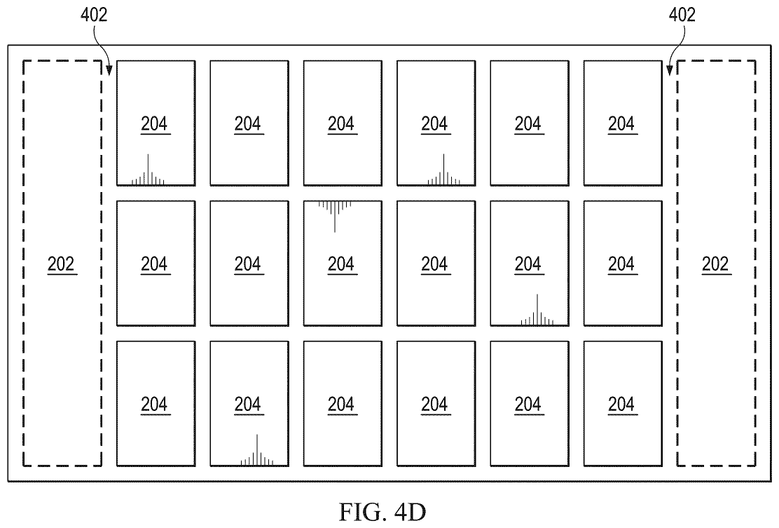

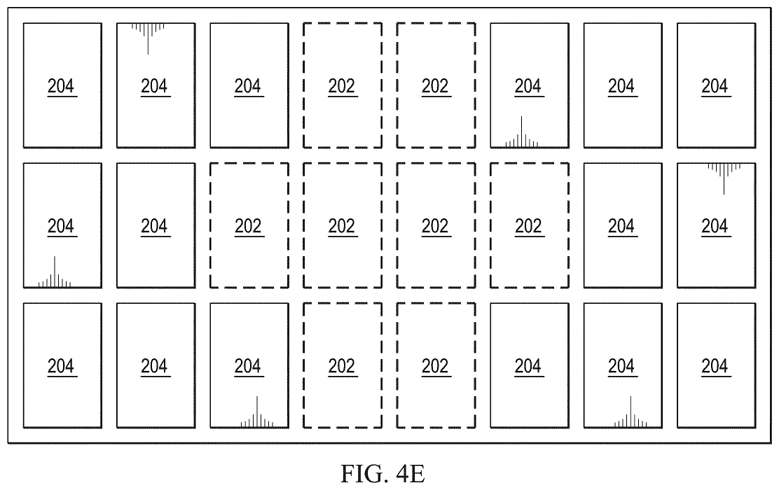

Referring to FIG. 2A, the semiconductor device 100 can include at least one first region 202 and a plurality of second regions 204. The first region 202 can include one or more capacitor units 210 (e.g., as illustrated in FIG. 2B). The second region 204 can include one or more memory blocks. Each memory block includes multiple memory cells (e.g., DRAM cells 124) and bit lines 123 as illustrated in FIG. 1. In some implementations, the first region 202 can be sandwiched by or centered in the second regions 204, as illustrated in FIG. 2A. Additional implementations of the semiconductor device 100 with varied arrangements of the first region 202 and second regions 204 are also described below in the descriptions of FIGS. 4A-4E.

FIG. 2B illustrates a schematic cross-section view of a capacitor array 200 in the first region 202. The capacitor array 200 includes one or more capacitor unit 210 and one or more loop-shaped conductive structures 220. Each capacitor unit 210 in the first region 202 includes a capacitor 206 and a semiconductor body 208. Each capacitor 206 corresponds to a respective semiconductor body 208. The capacitor 206 includes a first end 216 and a second end 218 opposite to the first end 216 along a direction perpendicular to the substrate surface. In the illustrated example in FIG. 2B, the substrate (e.g., the substrate 110 or the substrate 148 as illustrated in FIG. 1) extends along a Y direction, and the first end 216 and the second end 218 are positioned along a Z direction. The semiconductor body 208 includes a first end 212 and a second end 214 opposite to the first end 212 along the Z direction. The first end 212 of the semiconductor body 208 is coupled to a first end 216 of a respective capacitor 206. In some implementations, the second ends 218 of the capacitors 206 are connected to a ground plane 222. The ground plane 222 can be implemented as the common plate 146 in FIG. 1.

As noted above, in some implementations, a portion of the capacitors in the memory array can be used to provide capacitors to the CMOS circuits. Therefore, the capacitor units 210 can have substantially similar structures as 1T1C DRAM cells 124 in FIG. 1. In other words, the capacitor 206 in the first region 202 can have identical or substantially similar structures to those of the capacitors 128 in the second region 204 as depicted in FIG. 1. The semiconductor bodies 208 of the capacitor units 210 in the first region 202 can have identical or substantially similar structures to those of the transistor bodies 130 in the second region 204 as depicted in FIG. 1, except that the semiconductor bodies 208 may have doping levels different from the transistor bodies 130.

In some implementations, the semiconductor bodies 208 have a doping level similar to the first terminals 130a and second terminals 138b of the transistor 126. Consequently, rather than functioning as transistors, the semiconductor bodies 208 can be used as resistors in the capacitor array 200 in the first region 202. In some implementations, the resistance of one of the semiconductor bodies 208 can be ranged between 100 kiloohms to 500 kiloohms.

In some implementations, the semiconductor bodies 208 include doped polysilicon with a concentration of dopants greater than 1E15 dopant atoms per cubic centimeter. In some implementations, the dopants include at least one of Phosphorus (P), Arsenic (As), Boron (B) or Gallium (Ga). In some implementations, the dopants in the semiconductor bodies 208 can have a same conductivity type as those in the transistor bodies 130. For example, both the transistor bodies 130 and the semiconductor bodies 208 can have an N type doping or a P type doping. In some implementations, the dopants in the semiconductor bodies 208 can have different conductivity type from those in the transistor bodies 130.

As illustrated in FIGS. 2B-2C, a loop-shaped conductive structure 220 can be formed to connect with second ends 214 of the semiconductor bodies 208. The loop-shaped conductive structure 220 includes a pair of line segments 224 and a pair of end segments 226 adjoined to ends of the pair of line segments 224 (FIG. 2C). In some implementations, the pair of end segments 226 and the pair of line segments 224 can seamlessly form a single and unitary loop structure. In some implementations, each line segment of the pair of line segments 224 has uniform, substantially similar, or identical length along the direction of the bit lines, e.g., the Y direction. In some implementations, the pair of line segments 224 are coupled to second ends 214 of the semiconductor bodies 208 (FIG. 2B). The loop-shaped conductive structure 220 can be made of a conductive material including, but not limited to W, Co, Cu, Al, TiN, TaN, polysilicon, or any combination thereof. In some implementations, the loop-shaped conductive structure 220 is made of a composite conductive material that can be based on a metallic material (e.g., W, Co, Cu, Al) and a semiconductor material (e.g., Si). For example, the composite conductive material can include metal silicide, such as WSi, CoSi, CuSi, AlSi, or any other suitable metal silicide having higher conductivities than doped silicon. In some implementations, the loop-shaped conductive structure 220 can have the same material as the bit line 123 in FIG. 1.

As illustrated in FIG. 2C, each line segment 224 of the loop-shaped conductive structure 220 extends along a first direction, e.g., the Y-direction. Adjacent loop-shaped conductive structures 220 are arranged along a second direction, e.g., the X-direction or direction of the word lines, perpendicular to the first direction. Adjacent loop-shaped conductive structures 220 can be separated by a dielectric material, including without limitation to, silicon oxide, silicon nitride, silicon oxynitride, or any combination thereof.

As illustrated in FIG. 2B, the semiconductor device 100 further includes one or more paired conductive vias 230. The paired conductive vias 230 can also be referred to as a pair of conductive vias 230 in this disclosure. Each pair of conductive vias 230 (or each paired conductive vias 230) includes two conductive vias, e.g., a first conductive via 230a and a second conductive via 230b. First ends 232 of the paired conductive vias 230 are coupled to the pair of end segments 226 of the loop-shaped conductive structure 220. For example, the first conductive via 230a of the paired conductive vias 230 is coupled to a first end segment 226a of the pair of end segments 226, while the second conductive via 230b of the paired conductive vias 230 is coupled to a second end segment 226b of the pair of end segments 226.

Second ends 234 of the paired conductive vias 230 are coupled to a conductor 238. The conductor 238 can be coupled to a control circuitry, e.g., the peripheral circuits 112 in the first semiconductor structure 102. In some implementations, the paired conductive vias 230 and/or the conductor 238 are made of conductive materials, including without limitation to W, Co, Cu, Al, TiN, TaN, polysilicon, silicide, or any combination thereof. In some implementations, the paired conductive vias 230 and/or the conductor 238 includes multiple conductive layers, such as a W layer over a TiN layer.

In some implementations, the capacitors 206, the semiconductor bodies 208, the loop-shaped conductive structure 220, and the pairs of conductive vias 230 are in a semiconductor structure, e.g., the second semiconductor structure 104 depicted in FIG. 1. In some implementations, as illustrated in FIG. 1, the semiconductor device 100 further includes a control structure, e.g., the first semiconductor structure 102, bonded with the semiconductor structure, e.g., the second semiconductor structure 104. The control structure 102 includes the control circuitry, e.g., the peripheral circuits 112. In some implementations, the capacitors 206 are coupled to the control circuitry through the loop-shaped conductive structure 220, the paired conductive vias 230 and the conductor 238. Therefore, the capacitors 206 in the second semiconductor structure 104 can be provided for the peripheral circuits 112 in the first semiconductor structure 102. In some implementations, the conductor 238 is located in the first semiconductor structure 102. In some implementations, the conductor 238 is located in the second semiconductor structure 104. Although not shown, it is understood that the control circuit can also be located in the second semiconductor structure 104.

In some implementations, the first semiconductor structure 102 and the second semiconductor structure 104 are bonded with direct bonding. In some implementations, the direct bonding involves oxide bonding. The surfaces of the two semiconductor structures can be prepared by cleaning the surfaces thoroughly to remove any contaminants and oxides. An oxide layer can be grown or deposited on the surfaces of the first side of the two semiconductor structures. In some examples, the oxide layer includes silicon dioxide (SiO₂). The two semiconductor structures can be then aligned to have a proper match. The integrated semiconductor structures can be subjected to high-temperature annealing. During annealing, the oxide layer can become porous, and atoms at the interface can diffuse and rearrange, forming strong covalent bonds between the two semiconductor structures. After annealing, the bonded semiconductor structures can be gradually cooled down. This allows the formation of strong bonds between the semiconductor materials. It is understood that direct bonding can involve any other suitable techniques, e.g., molecular or atomic bonding.

In some implementations, the first semiconductor structure 102 and the second semiconductor structure 104 are bonded with hybrid bonding. A hybrid bonding can include a combination of metal-to-metal bonding and a direct oxide bonding. In some implementations, the second semiconductor structure 104 includes one or more first conductive contacts, e.g., the bonding contacts 121 (FIG. 1), isolated by a first dielectric material, e.g., the bonding layer 120. The control structure 102 includes one or more second conductive contacts, e.g., the bonding contacts 119 (FIG. 1), isolated by a second dielectric material, e.g., the bonding layer 118. The first conductive contacts can be in contact with the one or more second conductive contacts to form hybrid bonding.

FIG. 2D illustrate a schematic cross-sectional view of example memory arrays 250 in the second region 204. FIG. 2E illustrate a schematic plan view of bit lines and individual conductive vias of the memory arrays 250 in the second region 204. The memory cells 124 in the memory array 250 can have identical or substantially similar configurations to those depicted in FIG. 1. For ease of description, reference will be made to FIGS. 1, 2D and 2E when describing the structure of the memory arrays 250.

The memory array 250 includes memory cells, e.g., DRAM cells 124. Each memory cell 124 includes a transistor 126 and a capacitor 128. The transistor 126 includes the transistor body 130, the gate structure 136, the first terminal 138a and the second terminal 138b on opposite ends of the transistor body 130 (FIG. 1). The first terminal 138a of the transistor 126 is coupled to the capacitor 128.

The memory array 250 further includes bit lines 123. Each bit line 123 is coupled to corresponding second terminals 138b of the transistors 126, as shown in FIGS. 1 and 2D. In some implementations, the memory array 250 includes individual conductive vias 252. As illustrated in FIG. 2E, a first one 252a of the individual conductive vias 252 can be coupled to a first end 254 of a first bit line 123a of the bit lines 123. A second one 252b of the individual conductive vias 252 can be coupled to a second end 256 of a second bit line 123b adjacent to the first bit line 252a. The first end 254 of the first bit line 123a is opposite to the second end 256 of the second bit line 123b. In other words, the individual conductive vias 252 are located on opposite ends of adjacent bit lines 123.

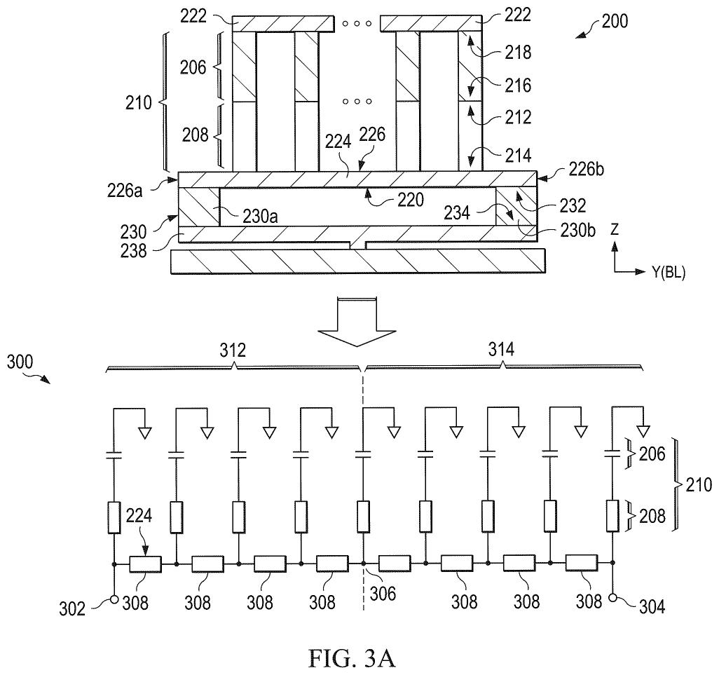

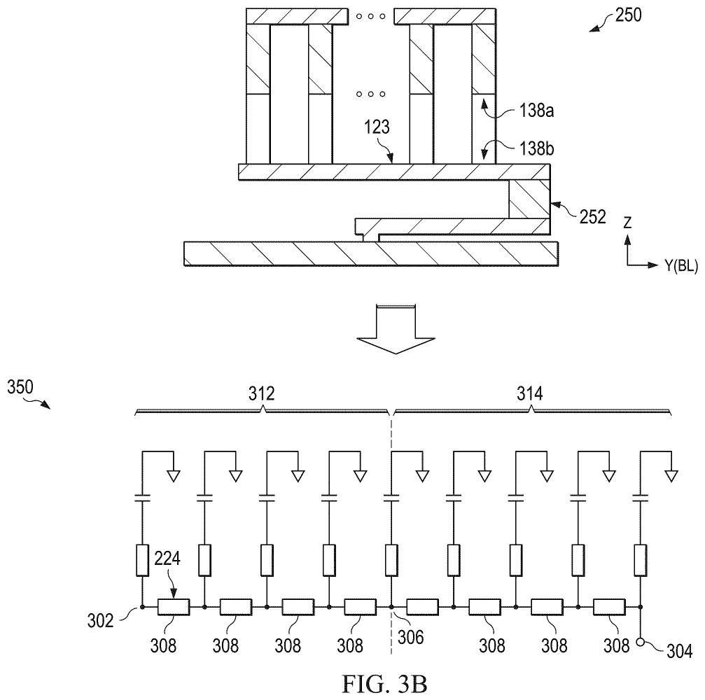

In some implementations, the first end 254 of the first bit line 123a extends beyond a first end 254 of the second bit line 123b along the bit line direction, e.g., the Y direction. For example, as shown in FIG. 2E, the bit lines 123 can have an alternating pattern where odd-numbered bars (e.g., the first bit line 123a) are shifted upward while even-numbered bars (e.g., the second bit line 123b) are shifted downward. This alternating configuration together with opposite individual conductive vias 252 can enlarge process window for forming individual conductive vias on the bit line and improve yield by reducing the risk of shorting between adjacent bit lines 123. It is to be noted that each bit line 123 of the memory array 250 in the second region 204 can be coupled to one conductive via on one end, whereas each line segment 224 of the loop-shaped conductive structure 220 in the first region 202 can be coupled to two conductive vias at both ends. This loop-shaped configuration may contribute to a reduction of resistance as described below with further details in FIGS. 3A-3B.

FIG. 3A illustrates a schematic view of equivalent circuits of the capacitor array 200. FIG. 3B illustrates a schematic view of equivalent circuits of the memory array 250.

As noted above, the capacitor array 200 can include one or more capacitor units 210. Each capacitor unit 210 includes a capacitor 206 and a resistor, e.g., the semiconductor body 208. In addition, the loop-shaped conductive structure 220 can include a pair of line segments 224. Each line segment 224 can be coupled to one or more capacitor unit 210. In the present example shown in FIG. 3A, each line segment 224 is coupled to nine capacitor units 210. In the equivalent circuit 300, each line segment 224 can be equivalent to eight resistor parts 308, with each resistor part 308 between adjacent capacitor units 210.

As noted above in FIGS. 2B-2C, each line segment 224 is adjoined to the end segments 226 and the end segments 226 are coupled to the paired conductive vias 230. The paired conductive vias 230 are further coupled to the conductor 238. Therefore, the two ends of the line segment 224, e.g., the first node 302 and the second node 304, are electrically connected and share the same electrical potential. Therefore, the resistance of the present example of the capacitor array 200 can be equivalent to the combined resistance of two portions that are arranged in parallel, e.g., a first portion 312 and a second portion 314 of the equivalent circuit 300. The first portion 312 of the equivalent circuit 300 can include the capacitor units 210 and the resistor parts 308 between the first node 302 and the middle node 306, and the second portion 314 of the equivalent circuit 300 includes the capacitor units 210 and the resistor parts 308 between the middle node 306 and the second node 304.

In contrast, for the equivalent circuit 350 of the memory array 250 as shown in FIG. 3B, only one end of the line segment 224, e.g., the second node 304, is connected to the individual conductive via 252. Therefore, the first node 302 and the second node 304 may have different electrical potentials. The resistance of the present example of the memory array 250 can thus be equivalent to the combined resistance of two portions that are arranged in series, e.g., the first portion 312 and the second portion 314 of the equivalent circuit 350. Therefore, the equivalent circuit 300 in FIG. 3A with loop-shaped conductive structures 220 can have a lower resistance than the equivalent circuit 350 in FIG. 3B. Low resistance in CMOS control circuits, e.g., the peripheral circuits 112, can have several benefits, such as faster operation, reduced power consumption, improved signal integrity, and/or better thermal performance.

FIGS. 4A-4E illustrate plan views of additional implementations of the semiconductor device 100 with varied arrangements of the first region 202 and second regions 204.

As noted above, the semiconductor device 100 can include one or more first regions 202 and one or more second regions 204. Each first region 202 can include one or more capacitor units 210 as described above in FIGS. 2B-2C. Each second region 204 can include one or more memory cells 124 as described in FIGS. 1, 2D and 2E. The one or more first regions 202 and the one or more second regions 204 can be separated from one another by a slit structure 402. In some implementations, the slit structure 402 can include a dielectric slit spacer (not shown) that separate adjacent regions. The slit spacer can be made of a material, including, but not limited to, silicon oxide, silicon nitride, silicon oxynitride, or any combination thereof. In some implementations, the slit structure 402 includes an inner conductive portion (not shown), e.g., including W, polysilicon, and/or TiN, circumscribed by the dielectric slit spacer.

It is to be understood that any one of the first regions 202 can be divided into a plurality of capacitor blocks (not shown). The capacitor blocks can be separated from one another by a dielectric structure, e.g., the slit structure. Each capacitor block can include one or more capacitor units 210. The plurality of capacitor blocks may vary in size, for example, having different numbers of capacitor units 210 in each capacitor block. In addition, or alternatively, the spacing between adjacent capacitor blocks within the same first region 202 may not be uniform.

As illustrated in FIGS. 4A, 4B and 4D, in some implementations, the second regions 204 are at least partially surrounded by, centered, or sandwiched in the first regions 202. In some implementations, the first regions 202 are symmetric about the second regions 204. In some implementations, as illustrated in FIGS. 4C and 4E, the first region 202 is centered in the second regions 204. The second regions 204 can be symmetric about the first regions 202. In some situations, symmetry may promote uniformity in the electrical characteristics, mitigate temperature variations in the semiconductor device 100, and provide better matching between resistors. Although not shown, it is to be understood that the first regions 202 and the second regions 204 can have unsymmetric arrangement or layout.

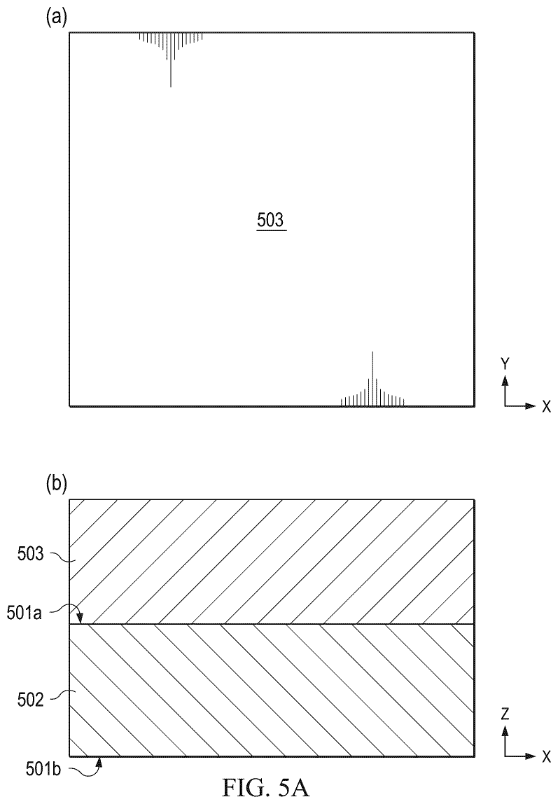

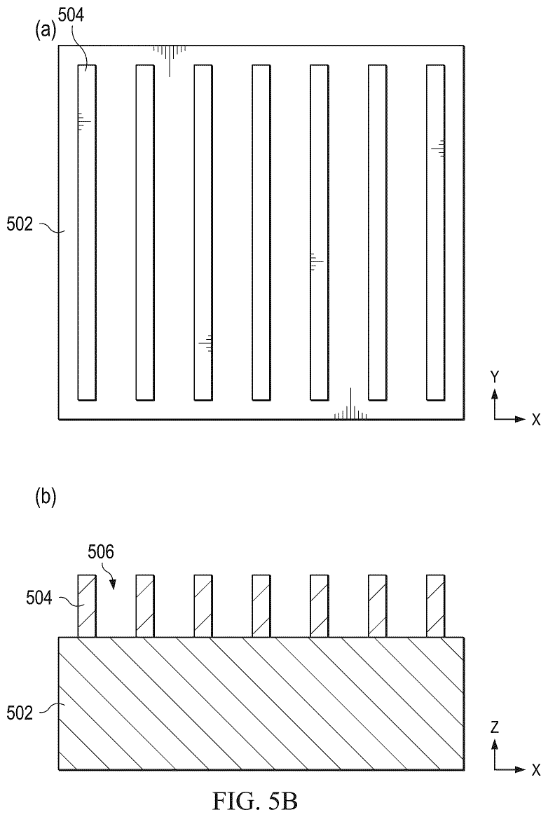

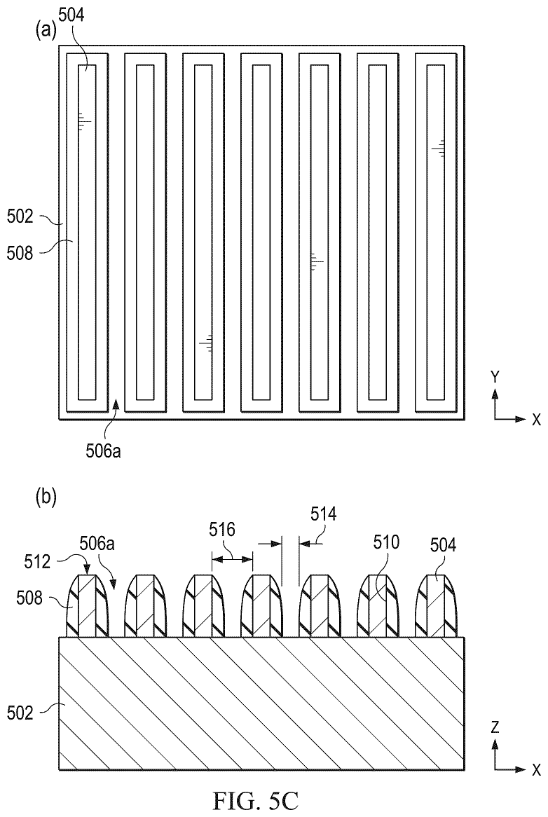

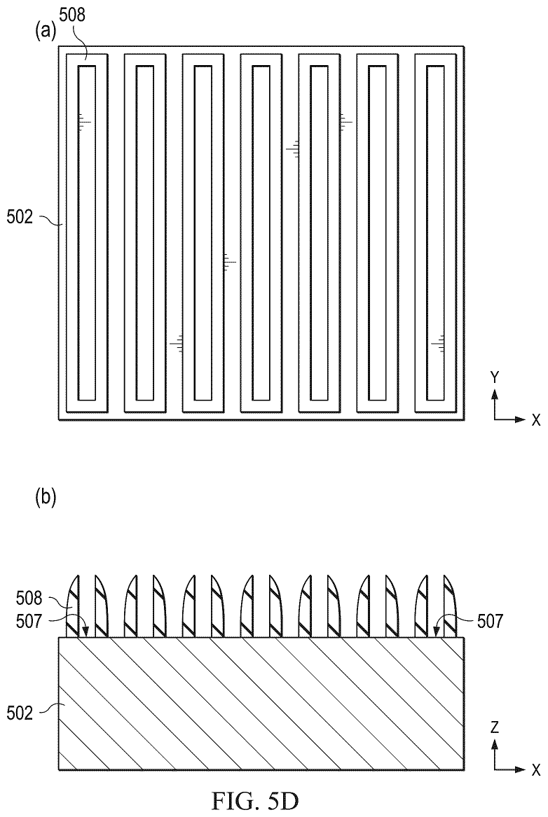

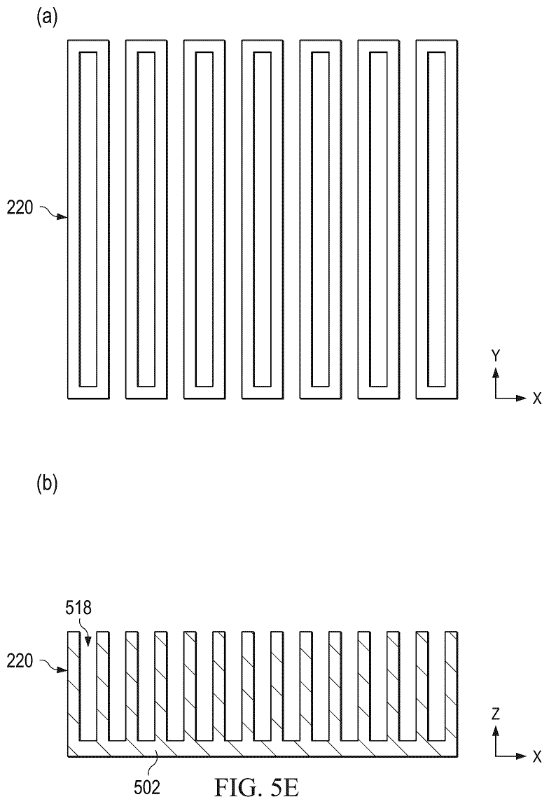

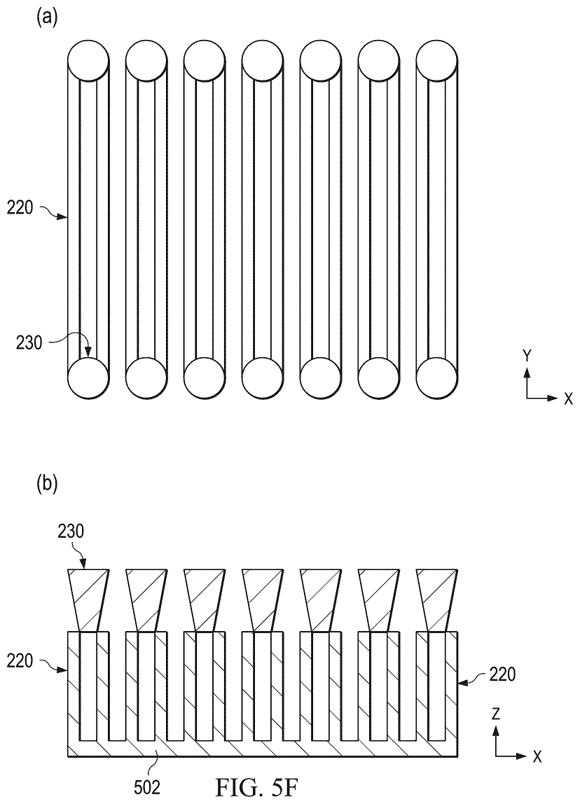

FIGS. 5A-5F illustrate top view and cross-sectional views of the semiconductor device 100 at various stages of an example process for forming the looped-shaped conductive structures 220 and the paired conductive vias 230. Each figure includes a plan view in X-Y plane in diagram (a) and a cross-sectional view in X-Z plane in diagram (b). The X-direction can be a direction of the word lines. The Y-direction can be a direction of the bit lines. The Z-direction can be a direction perpendicular to the substrate surface. For ease of description, reference will be made to both diagrams when describing each figure.

As illustrated in FIG. 5A, a hard mask layer 503 is deposited on a first side 501a of the substrate 502. The substrate 502 can include silicon (e.g., single crystalline silicon, c-Si), SiGe, GaAs, Ge, SOI, or any other suitable materials. The hard mask layer 503 can be made of materials including silicon nitride, silicon oxide, or silicon oxycarbide. In some implementations, the memory arrays 250 and the capacitor arrays 200 are formed on the second side 501b of the substrate 502. In some implementations, the hard mask layer 503 is formed on the first side 501a of the substrate 502 after the memory arrays 250 and the capacitor arrays 200 are formed on the second side 501b of the substrate 502. This process can involve employment of a carrier wafer (not shown) and a substrate thinning process. The carrier wafer can be bonded with the second side 501b of the substrate 502 after forming the memory arrays 250 and the capacitor arrays 200 on this side. After bonding, the combined structure is flipped over to allows access to the first side 501a of the substrate 502 to form the hard mask layer 503.

As illustrated in FIG. 5B, the hard mask layer 503 is patterned to form a plurality of separated hard mask structures 504 arranged along the X-direction. Each hard mask structure 504 can extend along the Y-direction. Adjacent hard mask structures 504 are separated by trenches 506. The trenches 506 can be formed by a plurality of processes including, but not limited to, photolithography, and/or etching. The etching process can involve one or more dry etching and/or wet etching techniques, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H₂SO₄/H₂O₂), or any combination thereof.

As illustrated in FIG. 5C, a spacer layer 508 is deposited into the trenches 506. In some implementations, the spacer layer 508 is formed on the sidewalls 510 of the hard mask structures 504. The spacer layer 508 may not completely fill the trenches 506, leaving some space 506a remaining inside the trenches 506. A width 514 of the remaining space 506a at the bottom of the trenches 506 can be smaller than a width 516 of the trenches 506 between adjacent hard mask structures 504. In some implementations, the spacer layer 508 are formed on the four lateral sidewalls 510 of the hard mask structure 504, forming a loop shape, as illustrated in diagram (a) of FIG. 5C. Adjacent loop-shaped spacer layers 508 are arranged along the X-direction and separated by the remaining space 506a of trenches 506. In some implementations, one or more of dry etching and/or wet etching are performed after the deposition of the spacer layer 508 to remove a portion of the spacer layer 508 to expose the top surfaces 512 of the hard mask structures 504.

The spacer layer 508 can be made of dielectric materials including, but not limited to, silicon oxide, silicon nitride, silicon oxynitride, or any combination thereof. The spacer layer 508 can be deposited using one or more thin film deposition techniques, including, but not limited to, chemical vapor deposition (CVD), physical vapor deposition (PVD), atomic layer deposition (ALD), sputtering, or any combination thereof.

As illustrated in FIG. 5D, the hard mask structures 504 are removed. The spacer layer 508 remains on the substrate 502, covering some portions of the substrate 502. The remaining portion 507 of the substrate 502 is exposed. The removal process can involve one or more dry etching and/or wet etching techniques, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H₂SO₄/H₂O₂), or any combination thereof. The etching process can be selective etching such that the etchants only etch the hard mask structures 504 or have a higher etch rate for the hard mask structures 504 than for the spacer layer 508.

As illustrated in FIG. 5E, an etching is performed to etch the exposed portion 507 of the substrate 502 and form substrate trenches 518 in the substrate 502. The loop-shaped spacer layers 508 can be used as a mask at this process step for transferring the loop-shaped patterned into the substrate 502. Therefore, the remaining portion of the substrate 502 can have a loop shape, which forms the loop-shaped conductive structures 220, as illustrated in diagram (a) of FIG. 5E. The spacer layers 508 can be subsequently removed after the etching is completed. The substrate trenches 518 can be formed by one or more dry etching and/or wet etching techniques, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H₂SO₄/H₂O₂), or any combination thereof.

As illustrated in FIG. 5F, the pairs of conductive vias 230 are formed on end segments 226 of the loop-shaped conductive structures 220. The process to form the pairs of conductive vias 230 can involve forming a dielectric layer (not shown) on the loop-shaped conductive structures 220, followed by an etching process to form holes (not shown) on the dielectric layer. The holes can be filled with a conductive material to form the pairs of conductive vias 230.

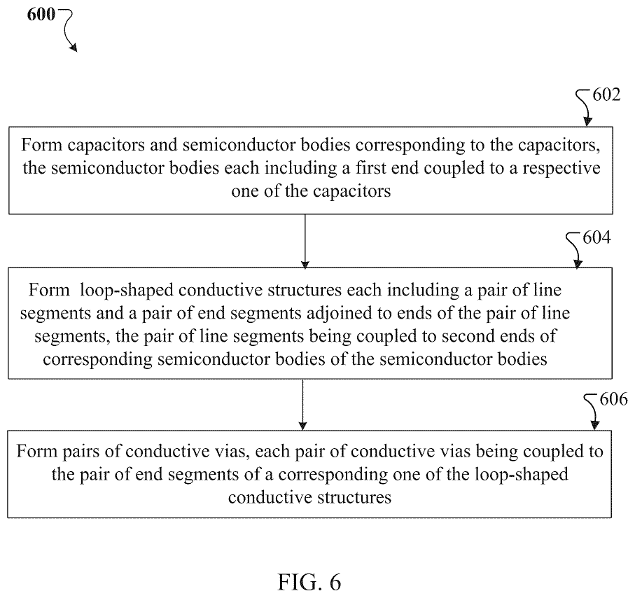

FIG. 6 illustrates a flow diagram of an example process for forming a semiconductor device 100. At step 602, capacitors and semiconductor bodies are formed corresponding to the capacitors. The semiconductor bodies each includes a first end coupled to a respective one of the capacitors. The capacitors can be, e.g., the capacitors 128 of FIGS. 1, 2D-2E and 3B, or the capacitors 206 of FIGS. 2B-2C and 3A. The semiconductor bodies can be, e.g., the semiconductor bodies 208 of FIGS. 2B-2C and 3A. The first end can be, e.g., the first end 212 of the semiconductor body 208 in FIG. 2B.

At step 604, loop-shaped conductive structures are formed. Each includes a pair of line segments and a pair of end segments adjoined to ends of the pair of line segments. The pair of line segments is coupled to second ends of corresponding semiconductor bodies of the semiconductor bodies. The loop-shaped conductive structures can be, e.g., the loop-shaped conductive structures 220 of FIGS. 2B-2C and 5E-5F. The pair of line segments can be, e.g., the line segments 224 of FIGS. 2B-2C, 3A and 5E-5F. The pair of end segments can be, e.g., the pair of end segments 226 of FIGS. 2B-2C and 5E-5F. The second ends of the semiconductor bodies can be, e.g., the second end 214 of the semiconductor body 208 in FIG. 2B.

At step 606, pairs of conductive vias are formed. Each pair of conductive vias is coupled to the pair of end segments of a corresponding one of the loop-shaped conductive structures. The pairs of conductive vias can be, e.g., the pairs of conductive vias 230 of FIGS. 2B-2C and 5F.

In some implementations, forming the loop-shaped conductive structures includes (i) forming dielectric structures on a semiconductor substrate; (ii) depositing a spacer layer on sidewalls of the dielectric structures; (iii) removing the dielectric structures; and (iv) etching an exposed portion of semiconductor substrate. The dielectric structures can be, e.g., the hard mask structures 504 of FIGS. 5B-5C. The spacer layer can be, e.g., the spacer layer 508 of FIGS. 5C-5D. The sidewalls of the dielectric structures can be, e.g., the sidewalls 510 of the hard mask structures 504 of FIG. 5C. The exposed portion of the semiconductor substrate can be, e.g., the exposed portion 507 of the semiconductor substrate 502 of FIG. 5D.

In some implementations, the semiconductor bodies include doped polysilicon with a concentration of dopants greater than 1E15 dopant atoms per cubic centimeter. In some implementations, the dopants include at least one of Phosphorus (P), Arsenic (As), Boron (B) or Gallium (Ga). In some implementations, the resistance of one of the semiconductor bodies is ranged between 100 kiloohms to 500 kiloohms.

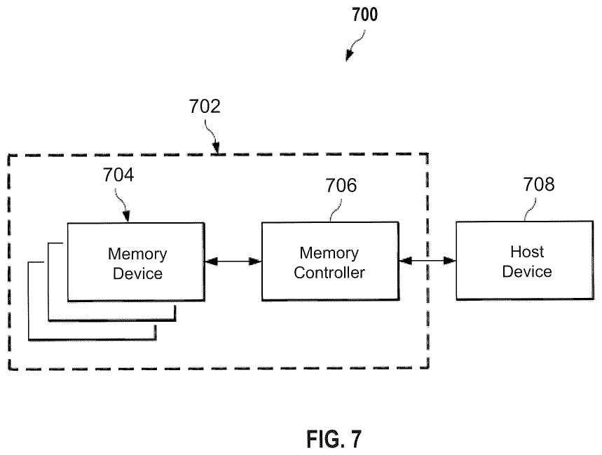

FIG. 7 illustrates a block diagram of a system 700 having one or more semiconductor device 100s (e.g., memory devices), according to one or more implementations of the present disclosure. The system 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 700 can include a host device 708 and a memory system 702 having one or more 3D memory devices 704 and a memory controller 706. Host device 708 can include a processor of an electronic device, such as a central processing unit (CPU), or a system-on-chip (SoC), such as an application processor (AP). Host device 708 can be configured to send or receive data to or from the one or more 3D memory devices 704.

A 3D memory device 704 can be any 3D memory device disclosed herein, such as the 3D semiconductor device 100 of FIGS. 1-2A and 4A-4E, or a part of the 3D semiconductor device 100 (e.g., the capacitor array 200 of FIGS. 2B-2C, the memory array 250 of FIGS. 2D-2E), or a structure at an intermediate fabrication process of the 3D semiconductor device 100 of FIGS. 5A-5F.

In some implementations, a 3D memory device 704 includes a NAND Flash memory. Memory controller 706 (a.k.a., a controller circuit) is coupled to 3D memory device 704 and host device 708. Consistent with implementations of the present disclosure, 3D memory device 704 can include a plurality of conductive interconnections through a cover layer that are in contact with conductive pads in a conductive pad layer, and memory controller 706 can be coupled to 3D memory device 704 through at least one of the plurality of conductive interconnections. Memory controller 706 is configured to control 3D memory device 704. For example, memory controller 706 may be configured to operate a plurality of channel structures via word lines. Memory controller 706 can manage data stored in 3D memory device 704 and communicate with host device 708.

In some implementations, memory controller 706 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 706 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 706 can be configured to control operations of 3D memory device 704, such as read, erase, and program (or write) operations. Memory controller 706 can also be configured to manage various functions with respect to the data stored or to be stored in 3D memory device 704 including, but not limited to bad-block management, garbage collection, logical-to-physical address conversion, wear leveling, etc. In some implementations, memory controller 706 is further configured to process error correction codes (ECCs) with respect to the data read from or written to 3D memory device 704. Any other suitable functions may be performed by memory controller 706 as well, for example, formatting 3D memory device 704.

Memory controller 706 can communicate with an external device (e.g., host device 708) according to a particular communication protocol. For example, memory controller 706 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 706 and one or more 3D memory devices 704 can be integrated into various types of storage devices, for example, be included in the same package, such as a universal Flash storage (UFS) package or an eMMC package. That is, memory system 702 can be implemented and packaged into different types of end electronic products. In one example as shown in FIG. 6, memory controller 706 and a single 3D memory device 704 may be integrated into a memory card 702. Memory card 702 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” “one implementation,” “an implementation,” “an example implementation,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−0.10%, .+−0.20%, or.+−0.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors 126 (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
capacitors and semiconductor bodies corresponding to the capacitors, the semiconductor bodies each comprising a first end coupled to an end of a respective one of the capacitors; and
a loop-shaped conductive structure comprising a pair of line segments and a pair of end segments adjoined to ends of the pair of line segments, the pair of line segments being coupled to second ends of the semiconductor bodies, the pair of end segments being coupled to a control circuitry.

2. The semiconductor device of claim 1, further comprising paired conductive vias, first ends of the paired conductive vias being coupled to the pair of end segments of the loop-shaped conductive structure, second ends of the paired conductive vias being coupled to a conductor, the conductor being coupled to the control circuitry.

3. The semiconductor device of claim 2, further comprising:
memory cells, each comprising a transistor and a capacitor, the transistor comprising a transistor body, a gate structure, a first terminal and a second terminal on opposite ends of the transistor body, the first terminal of the transistor being coupled to the capacitor;
bit lines, each being coupled to corresponding second terminals of the transistors; and
individual conductive vias, a first one of the individual conductive vias is coupled to a first end of a first bit line of the bit lines, a second one of the individual conductive vias is coupled to a second end of a second bit line adjacent to the first bit line, and the first end is opposite to the second end.

4. The semiconductor device of claim 2, wherein the capacitors, the semiconductor bodies, the loop-shaped conductive structure, and the paired conductive vias are in a semiconductor structure,
wherein the semiconductor device further comprises a control structure bonded with the semiconductor structure, the control structure comprising the control circuitry, and
wherein the capacitors are coupled to the control circuitry through the loop-shaped conductive structure, the paired conductive vias and the conductor.

5. The semiconductor device of claim 1, wherein the semiconductor bodies comprise doped polysilicon with a concentration of dopants greater than 1E15 dopant atoms per cubic centimeter.

6. The semiconductor device of claim 5, wherein the dopants comprise at least one of Phosphorus (P), Arsenic (As), Boron (B) or Gallium (Ga).

7. The semiconductor device of claim 1, wherein resistance of one of the semiconductor bodies ranges between 100 kiloohms to 500 kiloohms.

8. The semiconductor device of claim 1, wherein the pair of line segments of the loop-shaped conductive structure have a uniform length.

9. The semiconductor device of claim 3, wherein the semiconductor device comprises a first region and second regions, the first region comprising the capacitors, the semiconductor bodies, and the loop-shaped conductive structure, each of the second regions comprising the memory cells and the bit lines, and wherein the first region is centered in the second regions.

10. A semiconductor device, comprising:
loop-shaped conductive structures each comprising a pair of line segments and a pair of end segments adjoined to ends of the pair of line segments;
pairs of conductive vias, first ends of each pair of conductive vias being coupled to the pair of end segments of a corresponding one of the loop-shaped conductive structures; and
conductors each coupled to second ends of a corresponding pair of the pairs of conductive vias.

11. The semiconductor device of claim 10, wherein each line segment of the pair of line segments extends along a first direction, and the loop-shaped conductive structures are arranged along a second direction perpendicular to the first direction.

12. The semiconductor device of claim 10, further comprising:
capacitors and semiconductor bodies corresponding to the capacitors, the semiconductor bodies each comprising a first end coupled to an end of a respective one of the capacitors and a second end coupled to the pair of line segment of a corresponding one of the loop-shaped conductive structures.

13. The semiconductor device of claim 12, wherein the semiconductor bodies comprise doped polysilicon with a concentration of dopants greater than 1E15 dopant atoms per cubic centimeter.

14. The semiconductor device of claim 13, wherein the dopants comprise at least one of Phosphorus (P), Arsenic (As), Boron (B) or Gallium (Ga).

15. The semiconductor device of claim 12, wherein resistance of one of the semiconductor bodies ranges between 100 kiloohms to 500 kiloohms.

16. A method, comprising:
forming capacitors and semiconductor bodies corresponding to the capacitors, the semiconductor bodies each comprising a first end coupled to a respective one of the capacitors;
forming loop-shaped conductive structures each comprising a pair of line segments and a pair of end segments adjoined to ends of the pair of line segments, the pair of line segments being coupled to second ends of corresponding semiconductor bodies of the semiconductor bodies; and
forming pairs of conductive vias, each pair of conductive vias being coupled to the pair of end segments of a corresponding one of the loop-shaped conductive structures.

17. The method of claim 16, wherein forming the loop-shaped conductive structures comprises:
forming dielectric structures on a semiconductor substrate;
depositing a spacer layer on sidewalls of the dielectric structures;
removing the dielectric structures; and
etching an exposed portion of semiconductor substrate.

18. The method of claim 16, wherein the semiconductor bodies comprise doped polysilicon with a concentration of dopants greater than 1E15 dopant atoms per cubic centimeter.

19. The method of claim 18, wherein the dopants comprise at least one of Phosphorus (P), Arsenic (As), Boron (B) or Gallium (Ga).

20. The method of claim 16, wherein resistance of one of the semiconductor bodies ranges between 100 kiloohms to 500 kiloohms.
